(19) United States
(12) Patent Application Publication
(10) Pub. No.: US 2017/0256386 A1
(43) Pub. Date: Sep. 7, 2017

(54) Magnetic Spattering Coating Device and Target Device Thereof

(71) Applicants: Shenzhen China Star Optoelectronics Technology Co Ltd., Shenzhen, Guangdong (CN); Wuhan China Star Optoelectronics Technology Co., Ltd., Wuhan, Hubei (CN)

(72) Inventor: Tao ZHOU, Shenzhen, Guangdong (CN)

(73) Assignees: Shenzhen China Star Optoelectronics technology Co. Ltd., Shenzhen, Guangdong (CN); Wuhan China Star Optoelectronics Technology Co., Ltd., Wuhan, Hubei (CN)

(21) Appl. No.: 14/904,141

(22) PCT Filed: Dec. 11, 2015
(86) PCT No.: PCT/CN2015/097091

§ 371 Date: Jan. 11, 2016

(30) Foreign Application Priority Data
Nov. 24, 2015 (CN) 201510825083.2

(51) Int. Cl. H01J 37/34; C23C 14/34; C23C 14/35

(52) U.S. Cl. CPC H01J 37/3435; C23C 14/35; C23C 14/3407; H01J 37/3408; H01J 37/345

(57) ABSTRACT

A target device for a magnetic spattering coating device includes: a spattering target fixture; a target bearing plate installed on the spattering target fixture, for bearing a target; a magnetic pole device fixed on one surface of the spattering target fixture backing toward the target bearing plate, for producing a horizontal magnetic field on one surface of the target. A predetermined interval is formed between the magnetic pole device and corresponding margins of the target bearing plate. The present invention can not only enhances utilization of the target but also makes the thin film deposited on the substrate highly well-distributed.

### BACKGROUND OF THE INVENTION

1. Field of the Invention

The present invention relates to the technical field of vacuum coating, and more particularly, to a magnetic spattering coating device and a target device belonging to the magnetic spattering coating device.

2. Description of the Prior Art

Magnetic spattering is one kind of physical vapor deposition (PVD). Materials such as metal, semiconductor, and insulators are manufactured in the method of spattering. The merits of the method of spattering are simple devices used, easy to control, a large coated area, and strong adhesion, etc. Developed since 1970s, the method of magnetic spattering achieves high speed, low temperature, and low damage. The method of magnetic spattering is more widely adopted in the field of thin film manufacturing. For example, with the development of flat displays, indium tin oxide (ITO) conducting thin films are especially active and prominent in the field of thin film manufacturing. Particularly, displays using thin-film transistors (TFTs) or organic light-emitting diodes (OLEDs) tend to require ITO electrically conductive glass with highly uniform thin film layers.

The operational principle of the magnetic spattering coating device is that electrons collide with argon atoms when flying to the substrate in the electric field. New argon positive ions and negative ions are produced after argon atoms are ionized. New electrons fly to the substrate. Argon positive ions accelerate to fly to a cathode target in the electric field and bombard the surface of the target with high energy. As a result, the target spatters. Neutral target atoms or particles are deposited on the substrate and form a thin film when atoms or particles spatter. The produced secondary electrons are confined in the plasma area near the surface of the target by the influence of the electric field and the magnetic field. A large amount of argon positive ions are ionized to bombard the target in the plasma area. With repetitions, the thin film finishes being coated.

Different magnetic strengths in the magnetic field result in different densities of produced plasma in distribution and different spattering speeds. Accordingly, the surface of the target appears lumpy. For example, a magnetic spattering coating device used in the conventional technology comprises a magnetic monopole for scanning backwards and forwards. The use of the magnetic monopole improves the lumpy surface of the target due to the different densities of plasma in the left and right directions. However, the electrons move much slower on the two terminals of the surface of the target than on the middle of the target because the magnet decelerates in the original direction and accelerates in the backward direction on the two terminals of the surface of the entire target. On condition of the same area width, the speed is slow and spattering take long time. On condition of the same power, the target in the corresponding area is greatly etched, and the two terminals of the target become hollow. Finally, the utilization of the target is low and the produced thin film is not well-distributed.

### SUMMARY OF THE INVENTION

According to the present invention, a target device for a magnetic spattering coating device comprises: a spattering target fixture; a target bearing plate, installed on the spattering target fixture, for bearing a target; a magnetic pole device, fixed on one surface of the spattering target fixture backing toward the target bearing plate, for producing a horizontal magnetic field on one surface of the target. A predetermined interval is formed between the magnetic pole device and corresponding margins of the target bearing plate.

Furthermore, the magnetic pole device moves backwards and forwards between a first predetermined spot outside left margins of the target bearing plate and a second predetermined spot outside right margins of the target bearing plate.

Furthermore, the magnetic pole device moves backwards and forwards between a first predetermined spot outside left margins of the target bearing plate and a second predetermined spot outside right margins of the target bearing plate.

Furthermore, a interval between the left margins of the target bearing plate and the first predetermined spot is settled as a first interval, a interval between the right margins of the target bearing plate and the second predetermined spot is settled as a second interval, and the width of the first interval is equal to the width of the second interval.

Furthermore, a first accelerating/decelerating segment, an average speed segment, and a second accelerating/decelerating segment are arranged in order from the first predetermined spot to the second predetermined spot between the first predetermined spot and the second predetermined spot. The first accelerating/decelerating segment is opposite to the first interval. The average speed segment is opposite to an area occupied by the target bearing plate, and the second accelerating/decelerating segment is opposite to the second interval.

Furthermore, the first accelerating/decelerating segment faces toward the first interval, and the width of the first accelerating/decelerating segment is equal to the width of the first interval.

Furthermore, the second accelerating/decelerating segment faces toward the second interval, and the width of the second accelerating/decelerating segment is equal to the width of the second interval.

Furthermore, the target bearing plate is fabricated from copper.

According to the present invention, a magnetic spattering coating device comprising the target device as mentioned above is provided.

The present invention provides benefits as follows: When the ions of the bombardment target bombard the target, the target bearing plate of the bombardment target is opposite to the average speed segment, and the moving speed of the ions of the bombardment target is equal in the average speed segment. Since the ions of the bombardment target bombard the surface of the entire target with equal energy, the ions of the bombardment target is well-distributed on the surface of the bombarded target and the material on the entire surface of the target is equally consumed. In this way, the material on the two terminals of the target is not consumed faster than the material on the middle of the target is. It not only enhances utilization of the target but also makes the thin film deposited on the substrate highly well-distributed.

### BRIEF DESCRIPTION OF THE DRAWINGS

For better understanding embodiments of the present invention, the following detailed description taken in conjunction with the accompanying drawings is provided. Apparently, the accompanying drawings are merely for some of the embodiments of the present invention. Any ordinarily skilled person in the technical field of the present invention could still obtain other accompanying drawings without use laborious invention based on the present accompanying drawings.

FIG. 1 is a schematic diagram of a magnetic spattering coating device according to a preferred embodiment of the present invention.

FIG. 2 is a schematic diagram of the target device according to the preferred embodiment of the present invention.

### DETAILED DESCRIPTION OF THE PREFERRED EMBODIMENTS

The accompanying drawings are included to provide a further understanding of the invention, and are incorporated in and constitute a part of this specification. The drawings illustrate embodiments of the invention and, together with the description, serve to explain the principles of the invention.

For clarify, thicknesses of the layers and areas in the drawings are exaggerated. The invention is described below in detail with reference to the accompanying drawings, wherein like reference numerals are used to identify like elements illustrated in one or more of the figures thereof, and in which exemplary embodiments of the invention are shown.

The terms “first” or “second”, as used herein, are defined as one or more than one. The term “another”, as used herein, is defined as at least a second or more.

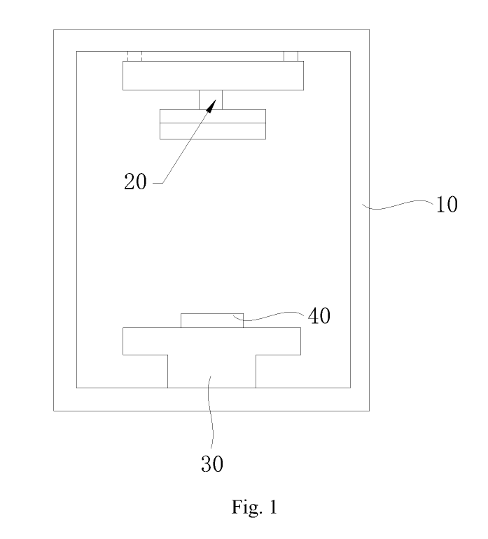

FIG. 1 is a schematic diagram of a magnetic spattering coating device according to one preferred embodiment of the present invention.

As FIG. 1 shows, the magnetic spattering coating device comprises a vacuum cavity 10, a target device 20, and a substrate bearing device 30. The target device 20 and the substrate bearing device 30 are installed in the vacuum cavity 10. The target device 20 is arranged opposite the substrate bearing device 30. The substrate bearing device 30 is used for bearing a substrate 40 waiting to be coated with a thin film. The target device 20 is used supplying spattering material. The spattering material is deposited on the substrate 40 and forms a thin film.

The target device 20 is arranged on the ceiling of the vacuum cavity 10, and the substrate bearing device 30 is arranged on the bottom of the vacuum cavity 10 in this embodiment. But it does not mean that the invention is limited. For example, the target device 20 is arranged inside the vacuum cavity 10 at the left side, and the substrate bearing device 30 is arranged inside the vacuum cavity 10 at the right side. The embodiment of the present invention details the target device below.

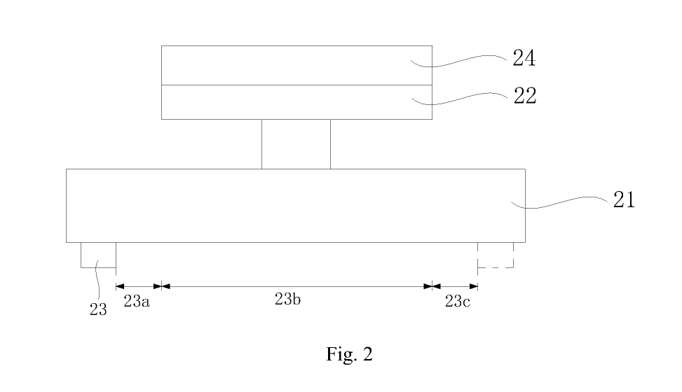

FIG. 2 is a schematic diagram of the target device according to the preferred embodiment of the present invention.

As FIG. 2 shows, the target device 20 comprises a spattering target fixture 21, a target bearing plate 22, and a magnetic pole device 23.

Specifically, the target bearing plate 22 is installed on the spattering target fixture 21. The target bearing plate 22 is used for bearing a target 24. The target bearing plate 22 is fixed on the spattering target fixture 21 in any appropriate fixing method in this embodiment.

The magnetic pole device 23 is fixed on one surface of the spattering target fixture 21 backing toward the target bearing plate 22. The magnetic pole device 23 is used for producing a horizontal magnetic field on one surface of the target 24.

Preferably, the magnetic pole device 23 is a magnet in this embodiment while it is not a limitation to the present invention. The magnetic pole device 23 moves backwards and forwards between a first predetermined spot outside left margins of the target bearing plate 22 and a second predetermined spot outside right margins of the target bearing plate 22. The magnetic pole device 23 (that is, a solid box as shown in FIG. 2) is set as the first predetermined spot, and a dotted box as shown in FIG. 2 is set as the second predetermined spot. Further, the magnetic pole device 23 moves backwards and forwards between the first predetermined spot and the second predetermined spot.

A interval between the left margins of the target bearing plate 22 and the first predetermined spot is settled as a first interval. A interval between the right margins of the target bearing plate 22 and the second predetermined spot is settled as a second interval. Further, the width of the first interval is equal to the width of the second interval.

Previous studies have shown that three segments will be formed between the first predetermined spot and the second predetermined spot when the magnetic pole device 23 moves backwards and forwards in a linear manner between the first predetermined spot and the second predetermined spot. The three segments are segmented according to the moving speed of the ions of the bombardment target 24 in each of the segments. Specifically, a first accelerating/decelerating segment 23a, an average speed segment 23b, and a second accelerating/decelerating segment 23c are arranged in order from the first predetermined spot to the second predetermined spot. The moving speed of the ions of the bombardment target in the first accelerating/decelerating segment 23a and the second accelerating/decelerating segment 23c is smaller than the moving speed of the ions of the bombardment target in the average speed segment 23b.

The first accelerating/decelerating segment 23a is opposite to the first interval between the first predetermined spot and the left margins of the target bearing plate 22. The average speed segment 23b is opposite to the area occupied by the target bearing plate 22. The second accelerating/decelerating segment 23c is opposite to the second interval between the second predetermined spot and the right margins of the target bearing plate 22.

Further, the first accelerating/decelerating segment 23a faces toward the first interval between the first predetermined spot and the left margins of the target bearing plate 22. The average speed segment 23b faces toward the area occupied by the target bearing plate 22. The second accelerating/decelerating segment 23c faces toward the second interval between the second predetermined spot and the right margins of the target bearing plate 22.

When the ions of the bombardment target 24 bombard the target 24, the target bearing plate of the bombardment target 24 is opposite to the 23b, and the moving speed of the ions of the bombardment target 24 is equal in the average speed segment 23b. Since the ions of the bombardment target 24 bombard the surface of the entire target 24 with equal energy, the ions of the bombardment target 24 is well-distributed on the surface of the bombardment target 24 and the material on the entire surface of the target 24 is equally consumed. In this way, the material on the two terminals of the target 24 is not consumed faster than the material on the middle of the target 24 is. It not only raises utilization of the target 24 but also makes the thin film deposited on the substrate highly well-distributed.

In addition, the width of the first accelerating/decelerating segment 23a is equal to the width of the first interval between the first predetermined spot and the left margins of the target bearing plate 22. The width of the average speed segment 23b is equal to the width of the target bearing plate 22. The width of the second accelerating/decelerating segment 23c is equal to the width of the second interval between the second predetermined spot and the right margins of the target bearing plate 22.

The target bearing plate 22 is fabricated from copper in this embodiment because copper has characteristics of excellent electrical conductivity and a higher melting point. But it is not a limitation to the present invention. In other words, the target bearing plate 22 can be fabricated from other kinds of materials as long as the materials have excellent electrical conductivity and a higher melting point.

In this embodiment, the target bearing plate 20 is arranged in the vacuum cavity 10. Based on this, the spattering target fixture 21 on the opposite side of the surface of the target bearing plate 22 is arranged on the ceiling of the the vacuum cavity 10. Also, the target bearing plate 22 of the bombardment target 24 faces toward the substrate bearing device 30 of the substrate 40.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A target device for a magnetic spattering coating device, comprising:
a spattering target fixture;
a target bearing plate, installed on the spattering target fixture, for bearing a target;
a magnetic pole device, fixed on one surface of the spattering target fixture backing toward the target bearing plate, for producing a horizontal magnetic field on one surface of the target;
wherein a predetermined interval is formed between the magnetic pole device and corresponding margins of the target bearing plate.

2. The target device of claim 1, wherein the magnetic pole device moves backwards and forwards between a first predetermined spot outside left margins of the target bearing plate and a second predetermined spot outside right margins of the target bearing plate.

3. The target device of claim 2, wherein the magnetic pole device moves backwards and forwards between a first predetermined spot outside left margins of the target bearing plate and a second predetermined spot outside right margins of the target bearing plate.

4. The target device of claim 2, wherein a interval between the left margins of the target bearing plate and the first predetermined spot is settled as a first interval, a interval between the right margins of the target bearing plate and the second predetermined spot is settled as a second interval, and the width of the first interval is equal to the width of the second interval.

5. The target device of claim 3, wherein a interval between the left margins of the target bearing plate and the first predetermined spot is settled as a first interval, a interval between the right margins of the target bearing plate and the second predetermined spot is settled as a second interval, and the width of the first interval is equal to the width of the second interval.

6. The target device of claim 4, wherein a first accelerating/decelerating segment, an average speed segment, and a second accelerating/decelerating segment are arranged in order from the first predetermined spot to the second predetermined spot between the first predetermined spot and the second predetermined spot;
the first accelerating/decelerating segment being opposite to the first interval, the average speed segment being opposite to an area occupied by the target bearing plate, and the second accelerating/decelerating segment being opposite to the second interval.

7. The target device of claim 5, wherein a first accelerating/decelerating segment, an average speed segment, and a second accelerating/decelerating segment are arranged in order from the first predetermined spot to the second predetermined spot between the first predetermined spot and the second predetermined spot;
the first accelerating/decelerating segment being opposite to the first interval, the average speed segment being opposite to an area occupied by the target bearing plate, and the second accelerating/decelerating segment being opposite to the second interval.

8. The target device of claim 6, wherein the first accelerating/decelerating segment faces toward the first interval, and the width of the first accelerating/decelerating segment is equal to the width of the first interval.

9. The target device of claim 7, wherein the first accelerating/decelerating segment faces toward the first interval, and the width of the first accelerating/decelerating segment is equal to the width of the first interval.

10. The target device of claim 8, wherein the second accelerating/decelerating segment faces toward the second interval, and the width of the second accelerating/decelerating segment is equal to the width of the second interval.

11. The target device of claim 9, wherein the second accelerating/decelerating segment faces toward the second interval, and the width of the second accelerating/decelerating segment is equal to the width of the second interval.

12. The target device of claim 1, wherein the target bearing plate is fabricated from copper.

13. A magnetic spattering coating device comprising a target device, the target device comprising:
a spattering target fixture;
a target bearing plate, installed on the spattering target fixture, for bearing a target;
a magnetic pole device, fixed on one surface of the spattering target fixture backing toward the target bearing plate, for producing a horizontal magnetic field on one surface of the target;
wherein a predetermined interval is formed between the magnetic pole device and corresponding margins of the target bearing plate.
